(19) United States
(12) Patent Application Publication
(10) Pub. No.: US 2016/0078966 A1
(43) Pub. Date: Mar. 17, 2016

(54) METHOD OF PERFORMING WEAR MANAGEMENT IN NON-VOLATILE MEMORY DEVICES

(71) Applicant: Transcend Information, Inc., Taipei (TW)

(72) Inventors: Tseng-Ho Li, Taipei City (TW); Yung-Ju Chen, New Taipei City (TW)

(21) Appl. No.: 14/485,779

(22) Filed: Sep. 14, 2014

(51) Int. Cl. G11C 29/10

(52) U.S. Cl. CPC G11C 29/10

(57) ABSTRACT

A method is provided for performing wear management in a non-volatile memory device which includes a plurality of storage units. A first error count associated with the amount of error bits generated in a specific storage unit during a first access is acquired. A second error count associated with an amount of error bits generated in the specific storage unit during a second access is retrieved, wherein the second access occurs earlier than the first access. An early retirement threshold is set to a first value when the difference between the first error count and the second error count does not exceed the predetermined value, or set to a second value smaller than the first value when the difference between the first error count and the second error count exceeds the predetermined value. The specific storage unit is marked as a bad storage unit when the first error count exceeds the early retirement threshold.

### BACKGROUND

1. Technical Field

The present invention is related to a method of performing wear management in a non-volatile memory device, and more particularly, to a method of performing wear management in read/write operations of a non-volatile memory device.

2. Description of the Conventional Art

Semiconductor memory devices are generally divided into two groups: volatile memory devices and non-volatile memory devices. Volatile memory devices include Dynamic Random Access Memory (DRAM) devices and Synchronous Random Access Memory (SRAM) devices. Non-volatile memory devices include Electrically Erasable Programmable Read Only Memory (EEPROM) devices, Ferroelectric Random Access Memory (FRAM) devices, Phase-change Random Access Memory (PRAM) devices, Magnetic Random Access Memory (MRAM) devices, and flash-type memory devices, etc. When power supply is cut off, volatile memory devices lose the data stored therein, while non-volatile memory devices can retain the data stored therein. Particularly, since flash-type memory devices are characterized in high programming speed, low power consumption and large-capacity data storage, they are widely used as non-volatile memory for computing devices such as desktop and laptop computers, personal digital assistants (PDAs), digital cameras, tablet computers, smartphones, and the like.

Flash-type memory devices, such as NOR-type flash-type memory devices with excellent random access time characteristics or NAND-type flash-type memory devices with high integration degree, may adopt different cell structures in which electric charges may be placed on or removed from a flash memory cell to configure the cell into a specific memory state. For example, a single level cell (SLC) may be configured to two single-bit binary states (i.e., 0 or 1). Similarly, a multi-level cell (MLC) may be programmed to two-bit states (i.e., 00, 01, 10, or 11), three-bit states, and so on.

Cells in flash-type memory devices suffer from the problem of wear, wherein the cell tunnel oxide becomes increasingly defective with Programming/Erase (P/E) cycle and the associated charge flow through the oxide is altered. As a result, some cells may become unable to hold a charge, or can only hold a charge for a short retention time. Several error detection/correction schemes have been introduced to ensure data integrity, but only a limited amount of error bits can be repaired. When many defective or low-retention cells cause error bits which are still repairable, the error rate of the block may become high enough that data written in the block cannot support a required level of reliability. Therefore, an early retirement scheme is also introduced for decommissioning blocks which do not meet reliability requirements before an unrepairable amount error bits are generated.

In a prior art wear management method, a constant early retirement threshold may be set to a value which is slightly smaller than the maximum number of repairable error bits. When the error bits detected in a specific block exceeds, the early retirement threshold, the specific block is marked as a bad block and decommissioned from further accesses. Generally speaking, the number of error bits is proportional to the P/E cycle. The error bits generated in a flash-type memory device normally increase gradually with its P/E cycle when the current P/E cycle is small, but increase exponentially with its P/E cycle when the current P/E cycle is large. When performing the prior art wear management method at a certain P/E cycle, the error count of a unreliable block may be smaller than but very close to the constant early retirement threshold. The exponential deterioration in performance may cause sudden increase in error bits only after a few P/E cycles. In other words, at the end of the guaranteed lifetime, the prior art wear management may not able to retire a soon-to-fail block in time. Therefore, there is a need for a method of performing wear management efficiently in non-volatile memory devices.

### SUMMARY

The present invention provides a method of performing wear management in a non-volatile memory device which includes a plurality of storage units. The method includes acquiring a first error count associated with an amount of error bits generated in a specific storage unit during a first access; retrieving a second error count associated with an amount of error bits generated in the specific storage unit during a second access, wherein the second access occurs earlier than the first access; determining if a difference between the first error count and the second error count exceeds a predetermined value; setting an early retirement threshold to a first value when the difference between the first error count and the second error count does not exceed the predetermined value or to a second value smaller than the first value when the difference between the first error count and the second error count exceeds the predetermined value; and marking the specific storage unit as a bad storage unit when the first error count exceeds the early retirement threshold.

The present invention also provides method of performing wear management in a read operation of a flash-type memory device which includes a plurality of blocks each having a plurality of pages. The method includes reading data from a first page in a first block of the flash-type memory device in response to a read command; moving data stored in the first block to a second block of the flash-type memory device when the first page meets an early move threshold, wherein the second block is erased and programmable; acquiring a first error count associated with an amount of error bits generated in a second page of the second block during a first read which occurs after moving the data stored in the first block to the second block; retrieving a second error count associated with an amount of error bits generated in the second page of the second block during a second read, wherein the second read occurs earlier than the first read; determining if a difference between the first error count and the second error count exceeds a predetermined value; setting an early retirement threshold to a first value when the difference between the first error count and the second error count does not exceed the predetermined value or to a second value when the difference between the first error count and the second error count exceeds the predetermined value; and marking the second block as the bad block when the first error count exceeds the early retirement threshold.

The present invention also provides a method of performing wear management in a write operation of a flash-type memory device which includes a plurality of blocks each having a plurality of pages. The method includes writing data into a specific page in a specific block of the flash-type memory device in response to a write command, wherein the specific block is erased and programmable; acquiring a first error count associated with an amount of error bits generated in a specific page of the specific block during a first write which occurs after writing the data into the specific page; retrieving a second error count associated with an amount of error bits generated in the specific page of the specific block during a second write, wherein the second write occurs earlier than the first write; determine if a difference between the first error count and the second error count exceeds a predetermined value; setting an early retirement threshold to a first value when the difference between the first error count and the second error count does not exceed the predetermined value or to a second value when the difference between the first error count and the second error count exceeds the predetermined value; and marking the specific block as the bad block when the first error count exceeds the early retirement threshold.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional diagram illustrating a non-volatile memory system for performing wear management according to an embodiment of the present invention.

FIG. 2 is a diagram illustrating the memory arrangement of the memory array in the flash-type memory device according to an embodiment of the present invention.

FIGS. 3-4 are diagrams illustrating the characteristic of the memory array during the executions of the present method.

FIG. 5 is a flowchart illustrating a method of performing wear management in a non-volatile memory system according to an embodiment of the present invention.

FIG. 6 is a flowchart illustrating a method of performing wear management in a read operation of a flash-type memory device according to an embodiment of the present invention.

FIG. 7 is a flowchart illustrating a method of performing wear management in a read operation of a flash-type memory device according to an embodiment of the present invention.

### DETAILED DESCRIPTION

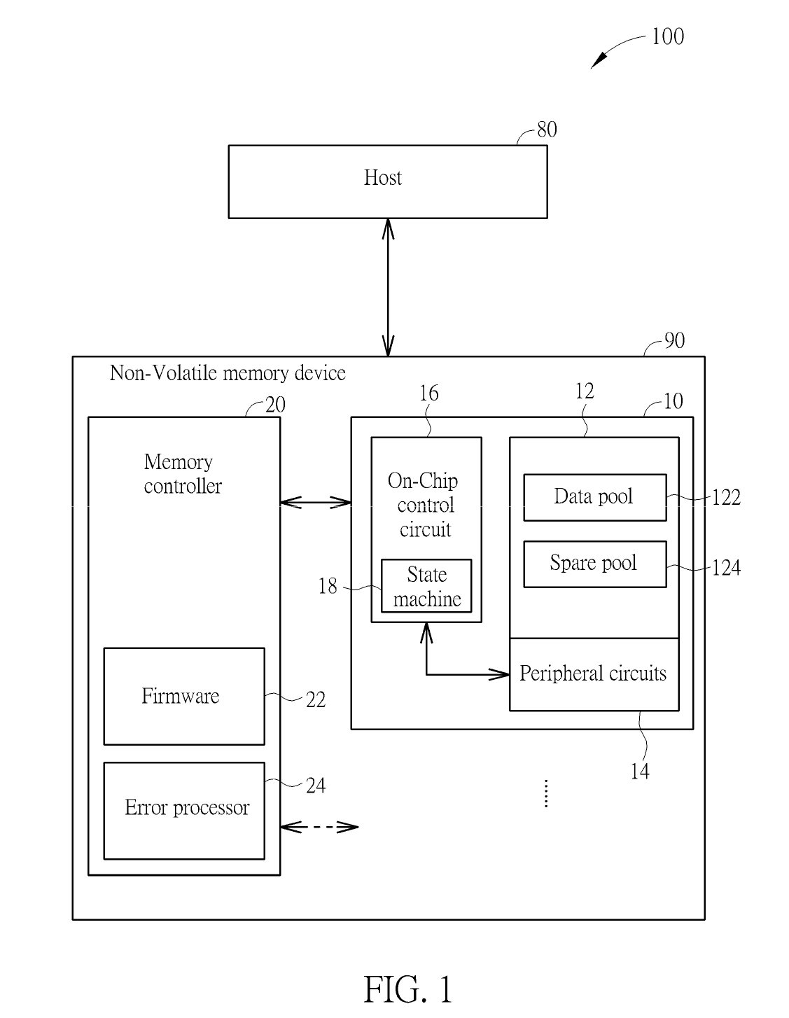

FIG. 1 is a functional diagram illustrating a non-volatile memory system 100 for performing wear management according to an embodiment of the present invention. The non-volatile memory system 100 includes a host 80 in communication with a memory device 90. The host 80 may send data to be stored to the memory device 90 (write operation) or retrieve data from the memory device 90 (read operation). The memory device 90 includes one or multiple memory chips 10 managed by a memory controller 20. Each memory chip 10 includes a memory array 12, peripheral circuits 14 and an on-chip control circuit 16. The memory array 12 consists of memory cells which may adopt MLC or SLC structure. In an embodiment, the memory array 12 includes a data pool 122 and a spare pool 124 for storing data. The peripheral circuits 14 may include row and column decoders, sense modules, data latches and I/O circuits (not shown). The on-chip control circuit 16 includes a state machine 18 and is configured to cooperate with the peripheral circuits 14 to control low-level memory operations on the memory array 12.

In many implementations, the host 80 is configured to communicate and interact with each memory chip 10 via the memory controller 20 which includes firmware 22 and an error processor 24. The firmware 22 provides codes to implement the functions of the memory controller 20. The error processor 24 is configured to detect and correct error bits in each smallest unit (ex: page) in the memory array 12 during operations of the memory device 90. Therefore, the memory controller 20 may cooperate with the memory chips 10 and control high-level memory operations on the memory arrays 12.

In the embodiments of the present invention, the memory device 90 may be an EEPROM device, an FRAM device, a PRAM device, an MRAM device, or a flash-type memory device. For illustrative purpose, a flash-type memory device 90 is used to explain the present invention in subsequent paragraphs. However, the type of non-volatile memory device does not limit the scope of the present invention.

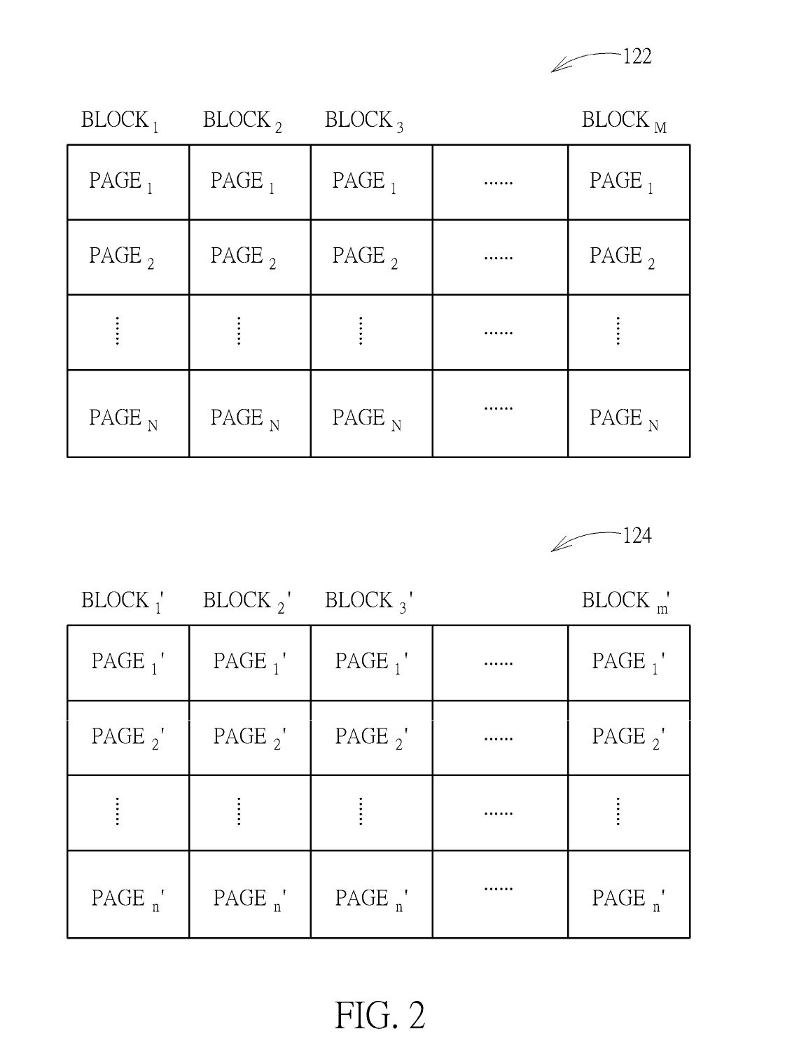

FIG. 2 is a diagram illustrating the memory arrangement of the memory array 12 in the flash-type memory device 90 according to an embodiment of the present invention. The data pool 122 includes a plurality of memory blocks BLOCK₁-BLOCK_{M}, each of which includes a plurality of pages PAGE₁-PAGE_{N} (M and N are positive integers). The spare pool 124 includes a plurality of spare blocks BLOCK₁′-BLOCKₘ′, each of which includes a plurality of pages PAGE₁′-PAGEₙ′ (m and n are positive integers). Generally in flash-type memory devices, a block is the smallest portion of the memory array 12 that can be erased, and a page is the smallest unit that can be written or read from the memory array 12. In an embodiment, the memory arrangement of the memory array 12 depicted in FIG. 2 may represent physical storage space on the flash-type memory device 90, such as by means of cylinder-head-sector (CHS) addressing. In another embodiment, the memory arrangement of the memory array 12 depicted in FIG. 2 may represent logical storage space on the flash-type memory device 90, such as by means of logical block address (LBA) addressing. However, the memory arrangement of the memory array 12 in the memory device 90 does not limit the scope of the present invention.

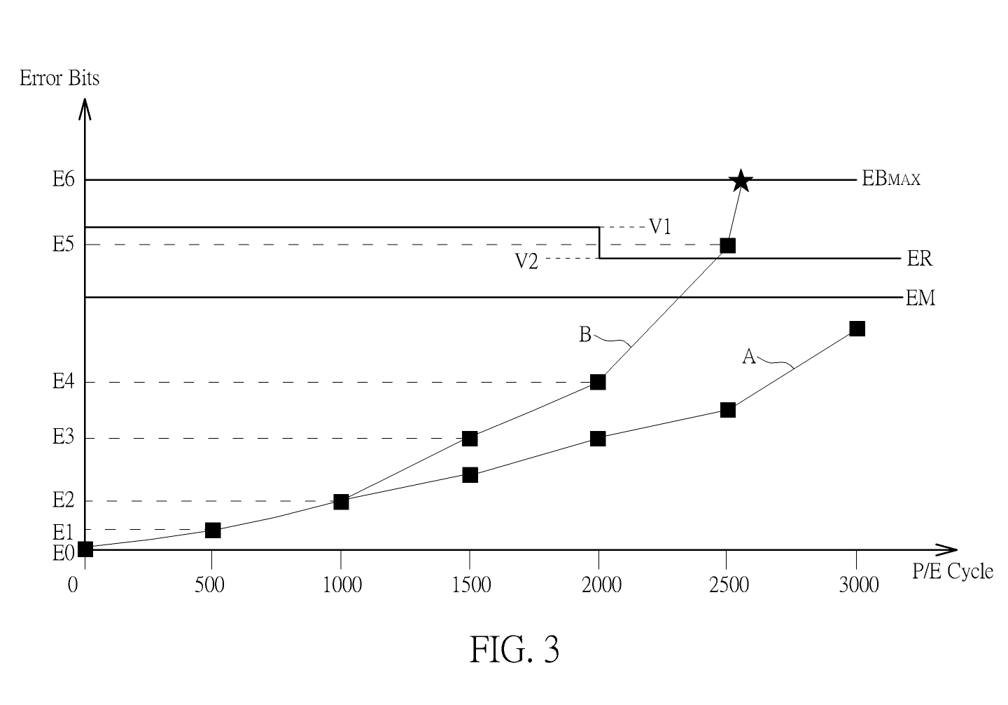

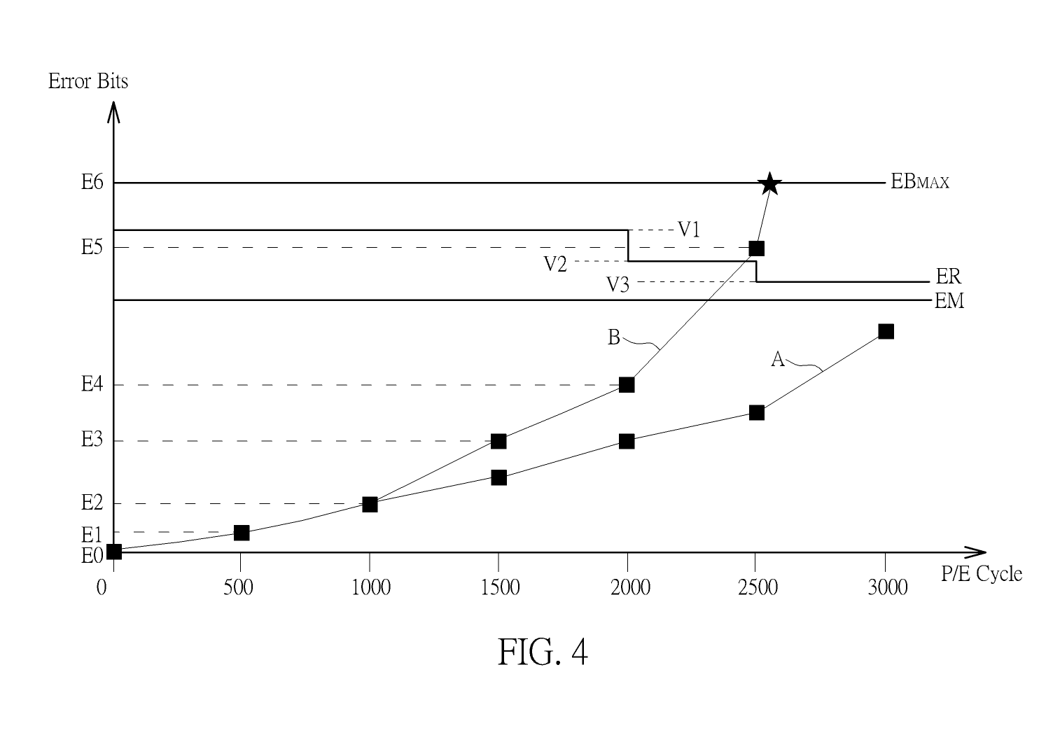

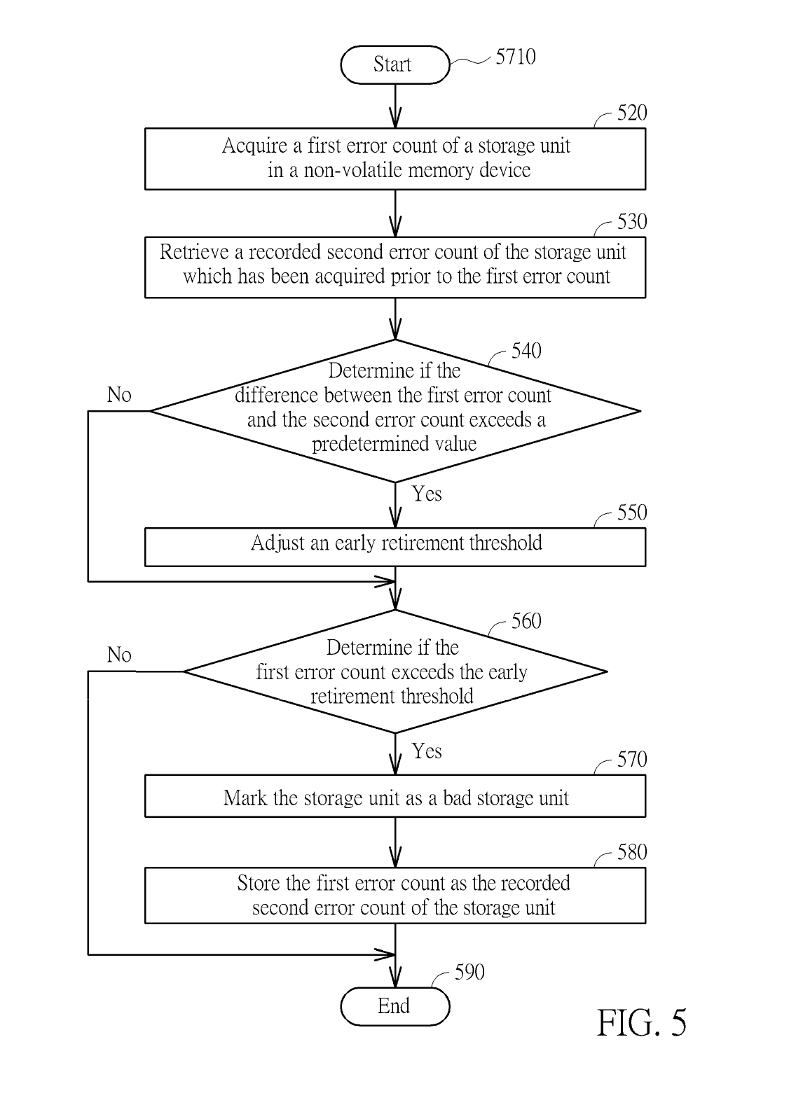

FIGS. 3-4 are diagrams illustrating the characteristic of the memory array 12 during the executions of the present method depicted in FIGS. 5-7. The horizontal axis represents the current P/E cycle of the flash-type memory device 90, and the vertical axis represents the error bits generated in the storage unit in the memory array 12. Curve A represents the ideal characteristic of a storage unit in the memory array 12, and curve B represents the characteristic of the storage unit in the memory array 12 when the flash-type memory device 90 encounters early failure. Curve EB_{MAX} represents an error bit limit associated with the maximum number of repairable error bits which can be generated in the storage unit without causing data loss. Curve EM represents the early move threshold for balancing data accesses of each storage unit. Curve ER represents the early retirement threshold for determining whether the storage unit can guarantee data integrity in the next access.

FIG. 5 is a flowchart illustrating a method of performing wear management in a non-volatile memory device according to an embodiment of the present invention. The flowchart in FIG. 5 includes the following steps:

Step 510: start.

Step 520: acquire a first error count of a storage unit in a non-volatile memory device; execute step 530.

Step 530: retrieve a recorded second error count of the storage unit which has been acquired prior to the first error count; execute step 540.

Step 540: determine if the difference between the first error count and the second error count exceeds a predetermined value; if yes, execute step 550; if no, execute step 560.

Step 550: adjust an early retirement threshold; execute step 560.

Step 560: determine if the first error count exceeds the early retirement threshold; if yes, execute step 570; if no, execute step 490.

Step 570: mark the storage unit as a bad storage unit; execute step 580.

Step 580: store the first error count as the recorded second error count of the storage unit; execute step 490.

Step 590: End.

The present wear management method depicted in FIG. 5 is now illustrated in accordance with FIGS. 1-4. For illustrative purpose, assume that the non-volatile memory system 100 is implemented with the flash-type memory device 90 with a guaranteed P/E cycle of 3000 for performing the present method depicted in FIG. 5. The storage unit maybe any of the memory blocks BLOCK₁-BLOCK_{M} in the memory array 12, or any of the pages PAGE₁-PAGE_{N} in any of the memory blocks BLOCK₁-BLOCK_{M} in the memory array 12. When the non-volatile memory system 100 is implemented with another type of the memory device 90 for performing the present method depicted in FIG. 4, different terms may be used when referring to the “storage unit”. However, how the “storage unit” is addressed in different types of non-volatile memory devices does not limit the scope of the present invention.

In the present invention, the method depicted in FIG. 5 may be performed on each storage unit of the non-volatile memory device in a predetermined order, or on a specific storage unit periodically or regularly based on P/E cycle. For example, the present wear management method depicted in FIG. 5 may be performed on a storage unit in the memory array 12 every 500 P/E cycles. However, the frequency and order when performing the present wear management method do not limit the scope of the present invention.

In the present invention, steps 520 and 530 may be executed by the error processor 24 using any known error detection scheme, such as repetition code, parity bit, checksum, cyclic redundancy check (CRC), cryptographic hash function or error correction code (ECC). One or multiple accesses may be required to measure the amount of error bits generated in a specific storage unit. However, the types of error detection scheme do not limit the scope of the present invention.

After performing step 520 on a specific storage unit, the currently acquired first error count maybe stored in a specific area of the specific storage unit, such as in the spare area of a page. In other words, the second error count retrieved in step 530 during the current execution is equal to the first error count acquired in step 520 during the previous execution. More specifically with reference made to FIGS. 3-4, if the method depicted in FIG. 5 is executed every 500 P/E cycles on a specific storage unit of the memory array 12, the first error counts acquired in step 520 are represented by E1-E5 and the second error counts retrieved in step 530 are represented by E0-E4 when the current P/E cycle of the flash-type memory device 90 reaches 500, 1000, 1500, 2000 and 2500, respectively.

In theory, each page in the blocks of the memory array 12 can be accessed without generating unrepairable amount of error bits before exceeding its guaranteed P/E cycle, as depicted by curve A in FIGS. 3-4. In some cases, with a guaranteed P/E cycle of 3000, the performance of the memory array 12 may rapidly degrade after its current P/E cycle reaches 2000 and the error bits generated in the memory array 12 may exceed the error bit limit EB_{MAX} when its current P/E cycle reaches around 2600 (represented by a star sign in FIGS. 3-4). The present method depicted in FIG. 5 provides an adjustable early retirement mechanism which prevents data loss due to early failure of the memory array 12, as depicted by curve B in FIGS. 3-4.

As previously stated, the error bits generated in the storage unit of the memory array 12 normally increase gradually with its P/E cycle when the current P/E cycle is small, and it may be determined in step 540 that the difference between the first error count and the second error count does not exceed the predetermined value represented by ΔE. In the embodiments illustrated in FIGS. 3 and 4, before the current P/E cycle of the flash-type memory device 90 reaches 2000, it may be determined in step 540 at each execution that E1-E0<ΔE, E2-E1<ΔE, and E3-E2<ΔE. Under such circumstance, the early retirement threshold ER maintained at an initial value represented by V1 is used in step 560.

On the other hand, the error bits generated in the storage unit of the memory array 12 normally increase exponentially with its P/E cycle when the current P/E cycle is large, and it may be determined in step 540 that the difference between the first error count and the second error count exceeds the predetermined value represented by ΔE. In the embodiment illustrated in FIGS. 3 and 4, when the current P/E cycle of the flash-type memory device 90 reaches 2000, it may be determined in step 540 at each execution that E4-E3>ΔE and E5-E4>ΔE. Under such circumstance, the early retirement threshold ER is adjusted to an updated value V2 smaller than V1 in step 550. During the next execution when the current P/E cycle of the flash-type memory device 90 reaches 2500, it may be determined in step 560 that the first error count exceeds the adjusted early retirement threshold (E5>V2). Even if the currently acquired first error count does not exceed the initial early retirement threshold (E5<V1), the storage unit is stilled marked as a bad storage unit in step 570. When the error count of a specific storage unit start to increase exponentially, an unrepairable amount of error bits may very likely be generated in the specific storage unit in the next few P/E cycles. By lowering the early retirement threshold in response to large increase in error count, the present invention can retire a soon-to-fail storage unit in time before it is worn-out, thereby ensuring data integrity.

In the present invention, the early retirement threshold for early retiring a specific storage unit is set to a larger value when the increase in error bits generated in the specific storage unit is small, and set to a smaller value when the increase in error bits generated in the specific storage unit is large. In the embodiment illustrated in FIG. 3, the early retirement threshold ER may be set to either V1 or V2 depending on whether the difference between the first error count and the second error count exceeds the predetermined value. In the embodiment illustrated in FIG. 4, the early retirement threshold ER may be lowered stepwise from V1, V2 to V3 at each execution after determining that the difference between the first error count and the second error count exceeds the predetermined value. However, the amount and frequency of the adjustment made to the early retirement threshold do not limit the scope of the present invention.

In the present invention, the predetermined value ΔE used in step 440 may be set according to according to the type, the characteristic and/or the ambient environment of the flash-type memory device 90, alone or in any combination.

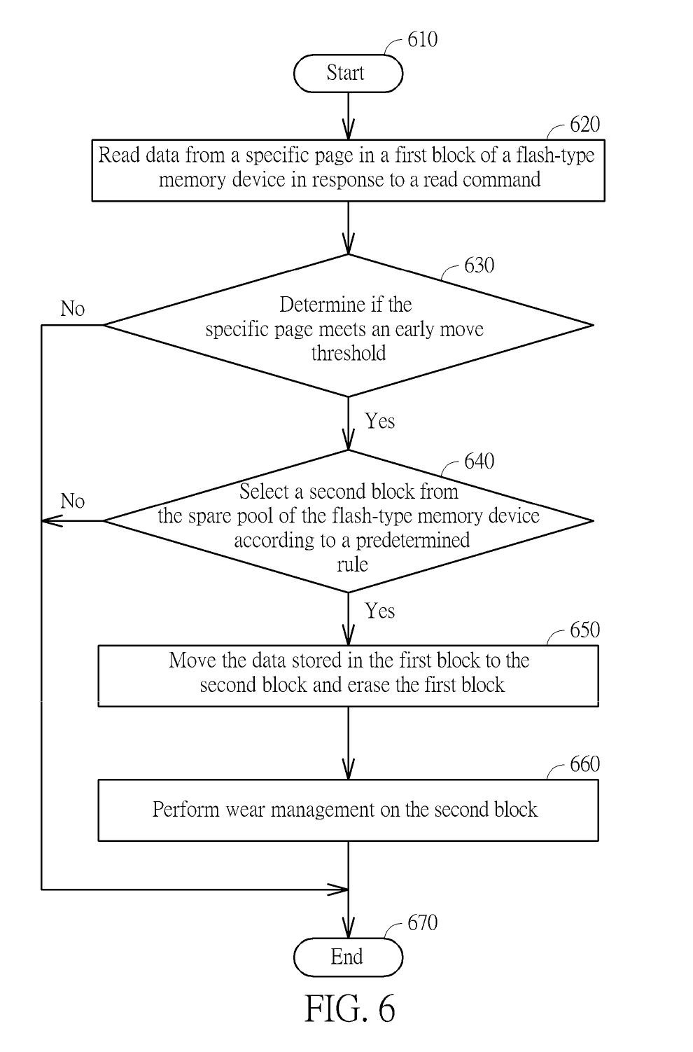

FIG. 6 is a flowchart illustrating a method of performing wear management in a read operation of a flash-type memory device according to an embodiment of the present invention. The flowchart in FIG. 6 includes the following steps:

Step 610: start.

Step 620: read data from a specific page in a first block of a flash-type memory device in response to a read command; execute step 630.

Step 630: determine if the specific page meets an early move threshold; if yes, execute step 640; if no, execute step 670.

Step 640: select a second block from the spare pool of the flash-type memory device according to a predetermined rule; execute step 650.

Step 650: move the data stored in the first block to the second block and erase the first block; execute step 660.

Step 660: perform wear management on the second block; execute step 670.

Step 670: end.

The present method depicted in FIG. 6 is now illustrated in accordance with FIGS. 1-4. For illustrative purpose, assume that the non-volatile memory system 100 is implemented with the flash-type memory device 90 with a guaranteed P/E cycle of 3000 for performing the present method depicted in FIG. 6. Also, all spare blocks in the spare pool 124 have been erased and are programmable for write operation.

After reading data from the specific page of the first block in response to the read command in step 620, it is determined in step 630 whether an early move operation should be performed on the specific page. In the present invention, step 630 maybe executed by acquiring an error bit count of the specific page using the error processor 24 based on any known error detection scheme, such as repetition code, parity bit, checksum, cyclic redundancy check, cryptographic hash function or error correction code, thereby determining if the error bit count of the specific page exceeds the early move threshold represent by curve EM in FIGS. 3-4.

In step 640, the second block is selected from the spare pool 124 of the flash-type memory device 90 according to the predetermined rule. In one embodiment, the second block may be any spare block which is randomly selected from the spare pool 124. In another embodiment, the second block may be the spare block which has the lowest error bit counts in the spare pool 124, thereby avoiding early wear-out of a particular spare block in the spare pool 124. In steps 630-650, the present invention provides an early move mechanism which prevents excessive use of a particular block before all blocks are fully used.

In step 660, the wear management method depicted in FIG. 5 may be performed on the second block. If the second block is marked as a bad block in step 660, it will be decommissioned, thereby preventing data to be relocated to an unreliable place in the early move operation during next execution. Therefore, the present invention can retire a soon-to-fail block of a flash-type memory device in time before it is worn-out, thereby ensuring data integrity.

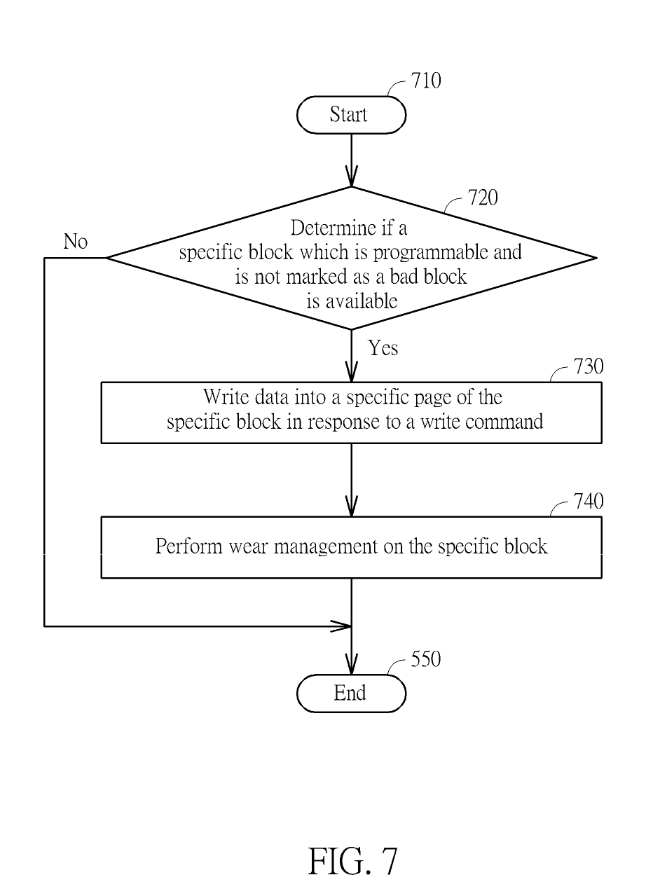

FIG. 7 is a flowchart illustrating a method of performing wear management in a write operation of a flash-type memory device according to an embodiment of the present invention. The flowchart in FIG. 7 includes the following steps:

Step 710: start.

Step 720: determine if a specific block which is programmable and is not marked as a bad block is available; if yes, execute step 730; if no, execute step 750.

Step 730: write data into a specific page of the specific block in response to a write command; execute step 740.

Step 740: perform wear management on the specific block; execute step 750.

Step 750: end.

The present method depicted in FIG. 7 is now illustrated in accordance with FIGS. 1-4. For illustrative purpose, assume that the non-volatile memory system 100 is implemented with the flash-type memory device 90 with a guaranteed P/E cycle of 3000 for performing the present method depicted in FIG. 7.

In step 720, it is determined if the specific block which is programmable and is not marked as a bad block is available. In step 730, data is written into the specific page of the specific block after verifying its reliability in step 720. In step 740, the wear management method depicted in FIG. 5 may be performed on the specific block. If the specific block is marked as a bad block in step 740, it will be decommissioned, thereby preventing data to be written into a unreliable place in subsequent write operation. Therefore, the present invention can retire a soon-to-fail memory block of a flash-type memory device in time before it is worn-out, thereby ensuring data integrity.

In the present invention, the early retirement threshold may be dynamically adjusted according to the increase in error bits generated in a storage unit of a non-volatile memory device. By lowering the early retirement threshold in response to large increase in error count, the present invention can retire a soon-to-fail storage unit in time before it is worn-out, thereby ensuring data integrity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of performing wear management in a non-volatile memory device which includes a plurality of storage units, the method comprising:
acquiring a first error count associated with an amount of error bits generated in a specific storage unit during a first access;
retrieving a second error count associated with an amount of error bits generated in the specific storage unit during a second access, wherein the second access occurs earlier than the first access;
determining if a difference between the first error count and the second error count exceeds a predetermined value;
setting an early retirement threshold to a first value when the difference between the first error count and the second error count does not exceed the predetermined value or to a second value smaller than the first value when the difference between the first error count and the second error count exceeds the predetermined value; and
marking the specific storage unit as a bad storage unit when the first error count exceeds the early retirement threshold.

2. The method of claim 1, further comprising:
setting the predetermined value according to at least one of a type, a characteristic or an ambient environment of the non-volatile memory device.

3. The method of claim 1, further comprising:
storing the first error count in the specific storage unit.

4. The method of claim 1, wherein the plurality of the storage units correspond to physical storage space of the non-volatile memory device.

5. The method of claim 1, wherein the plurality of the storage units correspond to logical storage space of the non-volatile memory device.

6. The method of claim 1, wherein the first value and the second value are smaller than a maximum number of error bits which can be repaired when a current Programming/Erase (P/E) cycle of the non-volatile memory device does not exceeds a guaranteed P/E cycle.

7. A method of performing wear management in a read operation of a flash-type memory device which includes a plurality of blocks each having a plurality of pages, the method comprising:
reading data from a first page in a first block of the flash-type memory device in response to a read command;
moving data stored in the first block to a second block of the flash-type memory device when the first page meets an early move threshold, wherein the second block is erased and programmable;
acquiring a first error count associated with an amount of error bits generated in a second page of the second block during a first read which occurs after moving the data stored in the first block to the second block;
retrieving a second error count associated with an amount of error bits generated in the second page of the second block during a second read, wherein the second read occurs earlier than the first read;
determining if a difference between the first error count and the second error count exceeds a predetermined value;
setting an early retirement threshold to a first value when the difference between the first error count and the second error count does not exceed the predetermined value or to a second value when the difference between the first error count and the second error count exceeds the predetermined value; and
marking the second block as the bad block when the first error count exceeds the early retirement threshold.

8. The method of claim 7, further comprising:
setting the predetermined value according to according to at least one of a type, a characteristic or an ambient environment of the flash-type memory device.

9. The method of claim 7, further comprising:
storing the first error count in a spare area of the second page; and
storing a bad block marker in the spare area of the second page for indicating whether the second block is marked as the bad block.

10. The method of claim 7, further comprising:
erasing the first block after moving the data stored in the first block to the second block.

11. The method of claim 7, wherein:
the early move threshold, the first value and the second value are smaller than a maximum number of error bits which can be repaired when a current P/E cycle of the non-volatile memory device does not exceeds a guaranteed P/E cycle; and
the first value and the second value are larger than the early move threshold.

12. A method of performing wear management in a write operation of a flash-type memory device which includes a plurality of blocks each having a plurality of pages, the method comprising:
writing data into a specific page in a specific block of the flash-type memory device in response to a write command, wherein the specific block is erased and programmable;
acquiring a first error count associated with an amount of error bits generated in a specific page of the specific block during a first write which occurs after writing the data into the specific page;
retrieving a second error count associated with an amount of error bits generated in the specific page of the specific block during a second write, wherein the second write occurs earlier than the first write;
determine if a difference between the first error count and the second error count exceeds a predetermined value;
setting an early retirement threshold to a first value when the difference between the first error count and the second error count does not exceed the predetermined value or to a second value when the difference between the first error count and the second error count exceeds the predetermined value; and
marking the specific block as the bad block when the first error count exceeds the early retirement threshold.

13. The method of claim 12, further comprising:
setting the predetermined value according to according to at least one of a type, a characteristic or an ambient environment of the flash-type memory device.

14. The method of claim 12, further comprising:
storing the first error count in a spare area of the specific page; and
storing a bad block marker in the spare area of the specific page for indicating whether the specific block is marked as the bad block.

15. The method of claim 12, wherein:
the first value and the second value are smaller than a maximum number of error bits which can be repaired when a current P/E cycle of the non-volatile memory device does not exceeds a guaranteed P/E cycle.
